(19) United States
(12) Patent Application Publication
(10) Pub. No.: US 2011/0262768 A1
(43) Pub. Date: Oct. 27, 2011

(54) METHOD FOR PRODUCING FITTINGS, LATERAL GRIDS AND SHELVES FOR HIGH TEMPERATURE APPLICATONS AND METAL COMPONENT

(75) Inventors: Peter Jährling, Bünde (DE); Willi Grigat, Bielefeld (DE)

(73) Assignee: PAUL HETTICH GMBH & CO. KG, Kirchlengern (DE)

(21) Appl. No.: 13/132,256

(22) PCT Filed: Dec. 2, 2009
(86) PCT No.: PCT/EP09/66231

§ 371 Date: Jul. 14, 2011

(30) Foreign Application Priority Data
Dec. 2, 2008 (DE) 102008059909.3

(51) Int. Cl. B32B 15/08; B32B 15/04; B32B 5/00; C23C 16/513

(52) U.S. Cl. 428/623; 427/569; 427/578; 428/457; 428/447; 428/336

(57) ABSTRACT

A method for producing a component of a pullout guide for high-temperature applications includes the method steps of: producing a metal blank; applying a plasma polymer coating to a surface of the blank; heating the coated blank to a temperature of at least 400° C.; and cooling the coated blank, thereby producing the component. A metal component is produced by the method. The component is used in combination with household appliances.

### SUBSTITUTE SPECIFICATION

This application is a national stage of International Application PCT/EP2009/066231, filed Dec. 2, 2009, and claims benefit of and priority to German Patent Application No. 10 2008 059 909.3, filed Dec. 2, 2008, the content of which Applications are incorporated by reference herein.

### BACKGROUND AND SUMMARY

The present disclosure relates to a method for producing a component such as side gratings or food supports, which may be on the form of pullout guides, for high-temperature applications and further relates to a metal component made according to the method.

Manufacturing components from self-passivating, stainless steels in the production of fittings, side gratings, and food supports is known. Surface passivation is typically performed in the case of a chromium content greater than 12%, whereby a chromium oxide layer is formed having a thickness of 2-4 nm. This passive layer protects the component from corrosion and prevents direct contact of the metal with another medium. The passivation by a chromium oxide layer has the advantage of being automatically passivating, that is, in the event of abrasion of the chromium oxide by scratches on the surface, new passivating chromium oxide immediately forms again from the underlying chromium layer upon contact with air oxygen.

However, further conditions must be fulfilled in addition to the chromium content for the formation of a uniform passive layer in the case of passivation. These are primarily a pure metal surface and sufficient oxygen to ensure complete oxidation along the surface. If these conditions are not fulfilled, a spontaneous oxide layer cannot be formed at high temperatures, such as, for example, temperatures from 450° C. in the case of self-passivating stainless steels, the corrosion resistance decreases, and a porous chromium oxide layer is formed as a result of scaling, which only allows slight corrosion protection. Therefore, the use of self-passivating stainless steels has proven to be disadvantageous for the manufacturing of components for cooking and baking ovens in the usage range from 400° C.

The present disclosure provides for a method of producing a component that improves the corrosion resistance of side gratings, fittings, and food supports. In addition, a metal component, produced according to the method, is provided for long-term use in baking ovens in the high-temperature range.

The present disclosure thus relates to a method for producing a component, such as a pullout guide, for high-temperature applications. The method steps include: producing a metal blank; applying a plasma polymer coating to a surface of the blank; heating the coated blank to a temperature of at least 400° C.; and cooling the coated blank, thereby producing the component. A metal component is produced by the method.

As noted above, the method steps include producing a metal blank, for example, by stamping and bending a metal plate, applying a plasma polymer layer to the surface of the blank, heating the coated blank to a temperature of at least 400° C., and cooling the coated blank to room temperature. A blank is thus provided which has good corrosion resistance even at high temperatures. In the case of coating of components for use in baking ovens, the surface, which was previously provided with a plasma polymer layer surprisingly proves to be sufficiently rugged to pass the stress tests after a thermal treatment.

Since the steps of the methods can also be automated, application in mass production is possible. The surface obtained by plasma polymer coating and thermal treatment causes improved corrosion protection over the prior passivation, even in the high-temperature range.

The presence of polar groups as a result of the plasma treatment also allows additional cross-linking of polymer strands among one another at higher temperatures and the rearrangement of the polymer strands to form bonds up to the formation of local crystallization zones. These capabilities result in solidification of the polymer material, in addition to the tear resistance of the amorphous sections of the polymer.

This additional strength of the plasma polymer surface, as a result of the thermal treatment, therefore makes it more resistant in relation to mechanical abrasion and ensures the maintenance-free usage of the components, which were produced according to the method of the present disclosure.

This strength is supported by diffusion of the plasma polymer compound into the surface of the metal blank.

A siliceous plasma polymer coating is may be provided. The coating forms a continuous solid SiO₂ layer, which both increases the corrosion resistance and also conceals tempering colors of stainless steels, and which may occur during the thermal treatment.

The plasma-polymer-coated blank may be temperature treated for at least 20 minutes, or more than 30 minutes, at 400-600° C. An adherent, corrosion-resistant, and substantially aging-resistant metal-polymer compound is thus achieved. The time of at least 20 or 30 minutes is advantageous for the cross-linking and reorientation of the polymer sections. Furthermore, heating of the plasma polymer layer up to 800° C. can result in a more robust, compact layer on the blank.

An embodiment of the coating, according to the present disclosure, may be advantageous because it provides a siliceous plasma polymer which is temperature-resistant in the range from 300-600° C. Silicon-oxygen polymer compounds, for example, silicones, are cost-effective, uncomplicated to synthesize, and chemically resistant with respect to a majority of chemicals. Because of their material properties, such polymers have manifold applications as construction materials or also as a coating material and therefore meet the requirements which are placed on a coating material for high-temperature use.

The heat treatment of the plasma polymer coating may be advantageously performed according to a temperature program, two different temperature gradients being used in a heating phase of the coated blank. Firstly, the blank is slowly heated up from room temperature, Θ₀=0-40° C., to a mean temperature Θ₁=80-200° C. A significantly more rapid heating phase is subsequently performed, to reach the corresponding target temperature Θ₂. The coating is, therefore, allowed to adjust to the altered conditions during the thermal expansion of the blank and to reorient itself if needed along the metal surface.

It may be advantageous to select a target temperature Θ₂ for the heating of the coating in the range 400-600° C., since this target temperature Θ₂ corresponds to the temperature during pyrolytic cleaning of a baking oven. A reorientation of polymer strands is possible at this target temperature. Further reorientation is typically no longer possible after the formation of bonds of the polymer strands among one another, and they can correspondingly withstand mechanical stresses, even in the high-temperature range.

In addition, it may be advantageous to maintain the target temperature Θ₂ over a period of time of 15 to 90 minutes, or possibly 25 to 40 minutes, since in this period of time reorientation of the polymer chains can occur, followed by the formation of additional bonds.

A high temperature gradient of 5-40 K/minutes, or possibly 15-25 K/minutes suggests itself during the cooling phase, whereby both the material resilience at the interface due to differing thermal expansion is minimized and also disorder in the material is prevented.

In another embodiment according to the present disclosure, which may also be advantageous, the coated blank is temperature-treated at an air flow rate of 30-90 l/minute, or possibly, 50-70 l/minute, whereby a bond of the plasma polymer on the metal surface is provided.

According to another embodiment of the present disclosure, the component is smoothed before the application of the plasma polymer layer. This is in order to achieve the largest possible interface between polymer and metal surfaces and additionally obtain a small spacing between both surfaces. The component can have a surface roughness of 300 to 500 nm, or possibly 300 to 400 nm, before the coating, which improves the adhesion of the polymer on the metal surface. Cleaning methods such as degreasing can be used before the application of the plasma polymer layer.

It may be advantageous if a metal, for example, chromium, diffuses into the plasma polymer layer by heating, which forms a passive layer under oxygen influence, so that in the event of damage of the coating of the component, for example, by scratches, a passive layer forms, which protects the metal surface situated underneath from corrosion. Chromium, for example, forms an oxide layer. Advantages of a chromium coating are therefore supplemented with the advantages of a plasma polymer coating.

This corrosion layer lengthens the service life of the component in the event of damage of the uppermost layer formed by the plasma polymer.

In order to ensure diffusion, the heating can be performed separately or during the curing of the coated component having the plasma polymer layer.

A component produced using the method according to the present disclosure is particularly usable in baking ovens in the high-temperature range. This is because the coating causes both a high material resilience and also a high temperature resistance. Foods, which normally contain a large amount of water, which vaporizes and condenses at another location, are typically cooked in a baking oven. A particular susceptibility to corrosion is thus provided in the case of components in a baking oven. In addition, value is to be placed on high-quality hygienic processing, in particular in this area of use.

It has also proven to be advantageous to implement a plasma polymer layer of 50-500 nm, or possibly 100-400 nm, along the surface of the metal. This layer allows the surface of the metal component to be left visible, so that the component is perceived as a metal component. The material composition of the transparent plasma polymer layer has the advantage that possible tempering colors of stainless steels are concealed without losing the metallic gloss and therefore a visual effect is achieved in the visible area of the oven.

Furthermore, it may be advantageous if the plasma polymer layer has at least 5%, or possibly 20-30% according to mass proportions, of a metal, for example, chromium. This forms a passive layer under oxygen influence, so that scratches and damage of the coating do not result in corrosion of the underlying metal and infiltration of the coating, but rather a passive layer forms at the area of the damage.

After the curing of the plasma polymer coating, the component can be constructed in such a way that the component includes multiple layers and includes at least one cover layer, one intermediate layer, and a base body made of metal. The cover layer comprises at least 80%, or possibly 90%, silicon oxide and is used as a wear layer with respect to abrasion, and also grease spatters, acids, bases, and mechanical stress for example, due to solids in household abrasive.

The intermediate layer includes at least silicon oxide or SiO₂ and at least one metal, which forms a passive layer for protection of the base material from corrosion in the event of damage to the cover layer by scratches and the like as a result of wear. While the silicon components ensure the stability of this layer, the metal allows a corrosion protection. The intermediate layer can contain further components in addition to silicon oxide and the metal. This configuration advantageously allows a longer service life of metal components and ensures a uniform metallic appearance.

The component, according to the present disclosure is well suitable for the production of a pullout guide, for example, the rails of the pullout guide can be coated accordingly.

In this component, the material is stressed by friction in such a way that the method, according to the present disclosure, represents a good alternative to previously existing methods for corrosion protection.

Other aspects of the present disclosure will become apparent from the following descriptions when considered in conjunction with the accompanying drawings.

### BRIEF DESCRIPTION OF THE DRAWINGS

FIG. 1 shows a perspective view of a pullout guide, according to the present disclosure.

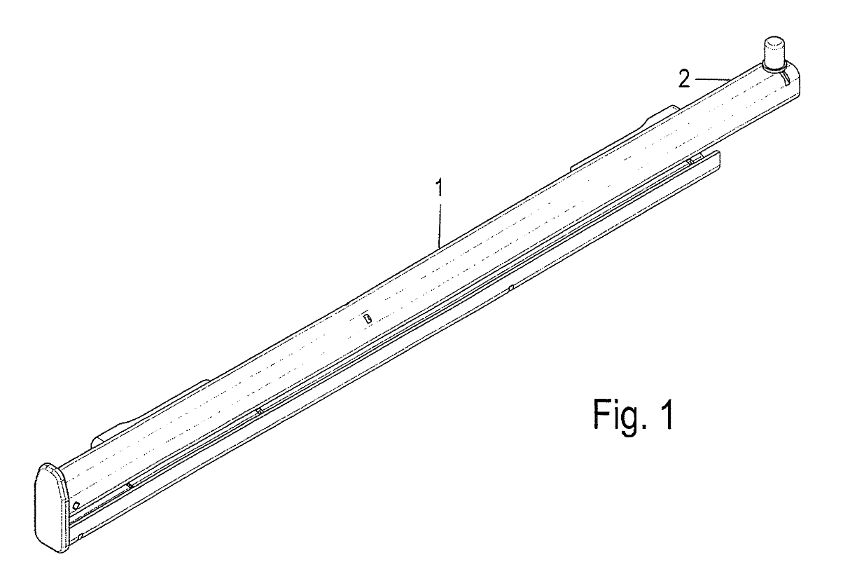

FIG. 2 shows an exploded view of the pullout guide of FIG. 1.

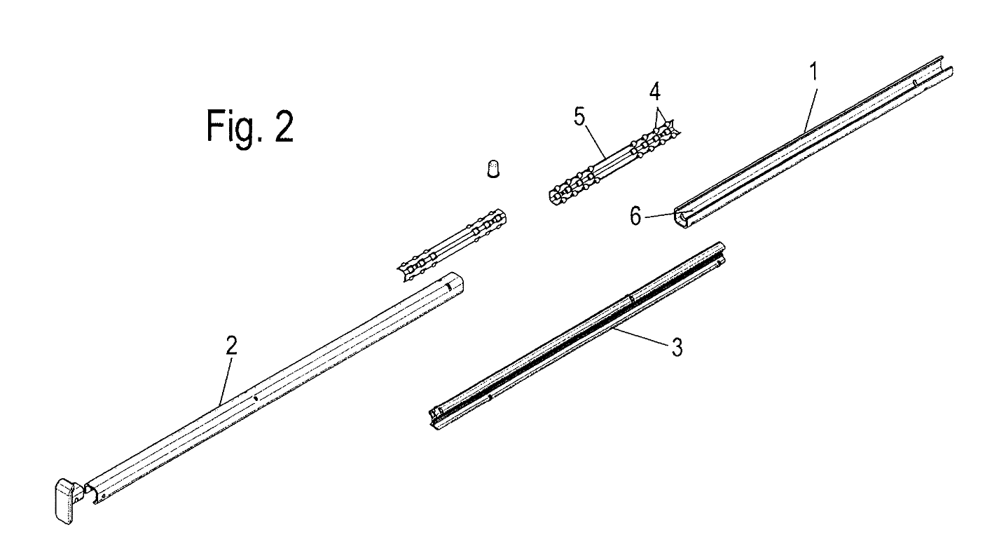

FIG. 3 shows a schematic temperature diagram for the production of a coated component, according to the present disclosure.

FIG. 4 shows a schematic diagram, according to the present disclosure.

FIG. 5 shows a schematic diagram, according to the present disclosure.

FIG. 6 shows a Table, according to the present disclosure.

### DETAILED DESCRIPTION

A pullout guide for high-temperature applications, for example, for baking ovens, comprises a guide rail 1 and a slide rail 2 movable relative to the guide rail 1, and between which a middle rail 3 is mounted. Pullout guides which only have a guide rail 1 and a slide rail 2 are known. Furthermore, pullout guides, which have a guide rail 1, a slide rail 2, and more than one middle rail 3, are also used. Roller bodies 4, for example, made of ceramic, are provided for the movable mounting of the middle rail 3 and the slide rail 2. Multiple runways 6 for the spherical roller bodies 4 are provided on the guide rail 1, the middle rail 3, and the slide rail 2.

The rails 1, 2 and 3 are produced for use in baking ovens from a stamped and bent steel plate and are provided with a coating. The production of the components of the pullout guide, in particular the rails 1, 2 and 3, is performed by the following steps, according to the present disclosure.

First, the metal blanks are produced by stamping and bending. The blank can be manufactured by machine. A plasma polymer layer is then applied to the surface of the blanks. The coated blanks are then heated to a temperature of at least 400° C. and temperature-treated for a predetermined period of time, before they are cooled down to room temperature again.

The application of the plasma polymer layer can be performed according to the present disclosure, for example, by functionalizing the polymer surfaces using reactive, typically polar groups through plasma modification and subsequent application thereof to a metal surface. Another possibility, according to the present disclosure, is direct plasma polymerization of monomers which are already located on a metal surface.

A plasma polymer has a functionalized surface, that is, polar groups which are formed by the targeted action of plasma. This functionalized surface can also form, in addition to adhesive forces, covalent bonds between the polar groups of the polymer surface and a metal surface. The basic structure of the polymer before the plasma treatment is just as decisive for the later properties of the polymer coating as the plasma irradiation itself. A plasma-modified Teflon layer on which metal adheres can thus additionally repel water, however. The length of the polymer chain at the contact points, for example, spacers determines their flexibility. It may be advantageous, in the case of plasma treatment of polymers, that the resulting functional groups can be chemically modified in such a way that they may be adapted to the metal surface.

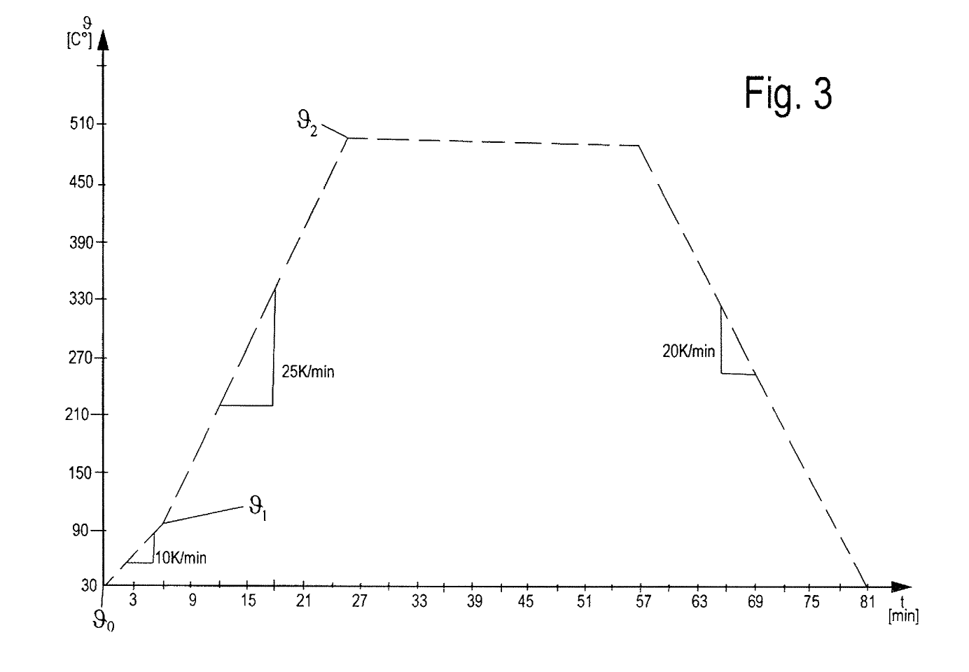

FIG. 3 schematically shows a temperature diagram for the method, according to the present disclosure, of permanent coating of fittings, side gratings, and food supports for high-temperature applications. The coated blank is initially heated from ambient temperature Θ₀. It begins using a temperature gradient of 10 K/minute starting from an initial temperature Θ₀ of 25° C. and then merges at a moderate temperature of Θ₁=100° C. into a temperature gradient of 25 K/minute. Upon reaching a target temperature Θ₂ of 500° C., a temperature plateau over 30 minutes follows. Finally, a cooling phase at 15 K/minute back to Θ₀ follows.

In an embodiment according to the present disclosure, a pullout guide has been described herein. Of course, it is within the scope of the present disclosure to provide other metal components with a coating according to the present disclosure. In particular, food supports, side gratings, fittings, or other components usable in baking ovens can be coated.

The results of a depth profile analysis of a plasma-polymer-coated pullout guide is shown below. The depth profile analysis is performed by glow discharge according to ISO 14707 and ISO/DIS 16962.2 at 650 V and 2 hPa.

TABLE 1
silicon oxide coating, without plasma polymer treatment

| Depth [μm] | Fe [%] | C [%] | O [%] | Si [%] | Cr [%] | S [%] |
|---|---|---|---|---|---|---|
| 0.030 | 5.530 | 6.210 | 6.000 | 76.691 | 3.672 | 0.189 |
| 0.120 | 60.310 | 3.162 | 2.399 | 0.551 | 31.297 | 0.081 |
| 0.210 | 63.380 | 1.189 | 1.144 | 0.402 | 32.296 | 0.034 |
| 0.300 | 66.120 | 0.657 | 0.621 | 0.336 | 30.981 | 0.019 |
| 0.700 | 72.990 | 0.156 | 0.163 | 0.263 | 25.575 | 0.003 |

TABLE 2
silicon oxide coating, without plasma - after 20 pyrolysis cycles

| Depth [μm] | Fe [%] | C [%] | O [%] | Si [%] | Cr [%] | S [%] |
|---|---|---|---|---|---|---|
| 0.030 | 0.380 | 0.613 | 0.809 | 97.892 | 0.118 | 0.032 |
| 0.120 | 37.080 | 8.812 | 28.806 | 3.837 | 17.221 | 0.469 |
| 0.210 | 59.190 | 3.651 | 13.818 | 1.825 | 19.763 | 0.170 |
| 0.300 | 65.01 | 2.108 | 8.444 | 1.238 | 22.117 | 0.103 |
| 0.700 | 71.520 | 0.596 | 2.646 | 0.590 | 24.145 | 0.031 |

TABLE 3
plasma - without pyrolysis

| Depth [μm] | Fe [%] | C [%] | O [%] | Si [% ] | Cr [%] | S [%] |
|---|---|---|---|---|---|---|
| 0.030 | 1.550 | 7.026 | 7.737 | 80.836 | 1.573 | 0.163 |
| 0.120 | 6.580 | 13.883 | 17.789 | 56.967 | 3.668 | 0.155 |
| 0.210 | 58.580 | 3.607 | 4.504 | 3.681 | 28.714 | 0.061 |
| 0.300 | 64.810 | 0.838 | 1.294 | 1.020 | 31.478 | 0.020 |
| 0.700 | 72.34 | 0.233 | 0.314 | 0.395 | 26.339 | 0.004 |

TABLE 4
plasma - fivefold pyrolysis

| Depth [μm] | Fe [%] | C [%] | O [%] | Si [%] | Cr [%] | S [%] |
|---|---|---|---|---|---|---|
| 0.030 | 0.685 | 3.232 | 2.935 | 91.923 | 0.201 | 0.100 |
| 0.120 | 15.107 | 12.222 | 28.711 | 40.311 | 2.083 | 0.226 |
| 0.210 | 46.194 | 2.154 | 16.011 | 4.070 | 31.874 | 0.047 |
| 0.300 | 74.150 | 0.447 | 3.163 | 1.109 | 18.910 | 0.016 |
| 0.700 | 76.600 | 0.148 | 0.578 | 0.411 | 20.711 | 0.003 |

TABLE 5
plasma - 20-fold pyrolysis

| Depth [μm] | Fe [%] | C [%] | O [%] | Si [%] | Cr [%] | S [%] |
|---|---|---|---|---|---|---|
| 0.030 | 0.360 | 1.026 | 1.062 | 97.091 | 0.201 | 0.039 |
| 0.120 | 17.760 | 14.313 | 23.826 | 40.764 | 2.083 | 0.229 |
| 0.210 | 44.770 | 6.222 | 32.387 | 9.771 | 6.013 | 0.099 |
| 0.300 | 64.700 | 1.661 | 11.495 | 2.891 | 18.910 | 0.024 |
| 0.700 | 77.070 | 0.161 | 1.219 | 0.491 | 20.711 | 0.003 |

The listed measurement results were performed on an alloy stainless steel surface made of an iron-chromium alloy as the base material. A siliceous coating was applied in each case to a pullout guide. The percent specifications relate to the prevailing mass concentration at a defined surface depth.

The results of Table 1 are to be attributed to a polymer coating which was not functionalized beforehand by plasma treatment.

The results of Table 2 also result from the analysis of a polymer coating without plasma treatment using the base material, which was subjected to 20 pyrolysis cycles, however.

A comparison of the measured values of Table 1 to Table 2 shows that the iron and chromium content has dropped by more than one-third at a surface depth of 0.12 μm. The mass concentration of oxygen has simultaneously risen from 2.4% to 28.8%. This is because of the scaling of the iron material on the surface. A silicon oxide film forms on the surface and only penetrates to a small extent, that is, 1-3.5% into the metal surface.

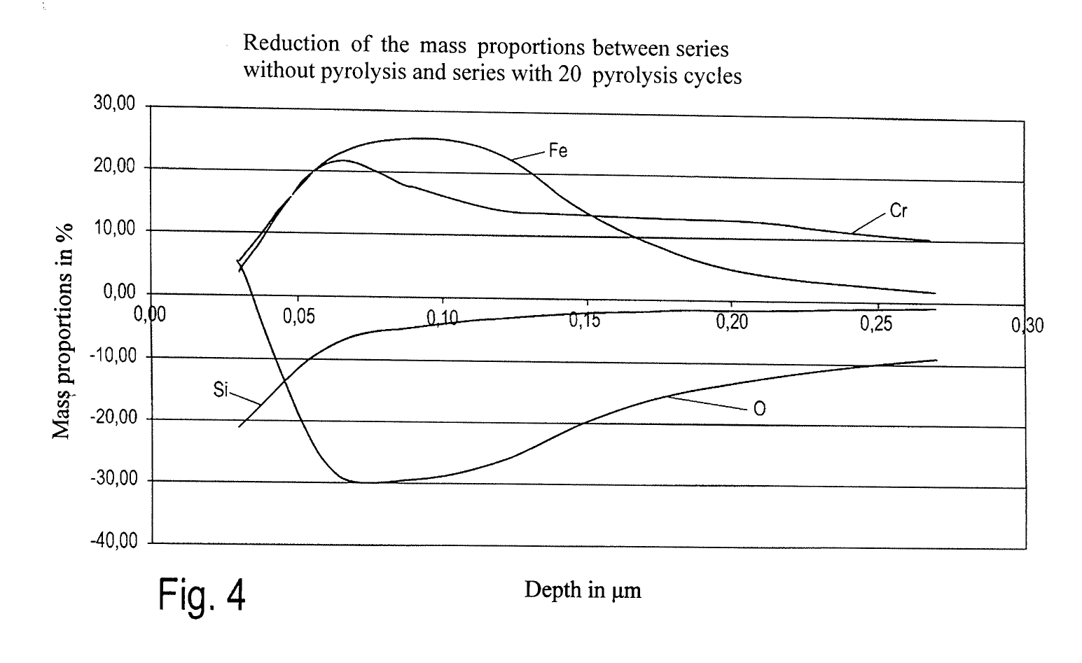

Diagram D1, or FIG. 4, shows the curve of the differences of the mass concentrations along the depth profile of the iron-chromium surface having the siliceous coating. The differences result from measured values of the depth profile before and after a twenty-fold pyrolysis. Scaling of the stainless steel surface occurs with formation of various iron-oxygen compounds.

A layer made of silicon only penetrates 1-2% into the metal surface.

The measurement results of Tables 3-5 were performed on surfaces which comprise the same metal base material, that is, an alloyed stainless steel, and are provided with a siliceous plasma coating.

The measurement results of Table 3 show the proportion of the components of the plasma polymer coating and the base material after the application, without further treatment of the layer.

The measurement results of Table 4 show the proportions of the components of the plasma polymer coating and the base material after five pyrolysis cycles.

The measurement results of Table 5 specify the proportions of the components of the plasma polymer coating and the base material after twenty pyrolysis cycles.

After 5 pyrolysis cycles, the formation of a surface-covering silicon oxide layer is terminated. After 20 pyrolysis cycles, the silicon oxide has additionally diffused into the surface of the base material, as shown by the increase of the mass concentration in Table 5 at 0.21 and 0.30 μm in relation to the measured values of Table 5. The plasma coating has therefore additionally penetrated or diffused into the base material surface during multiple pyrolysis cycles and has a thickness of approximately 10-30 μm, or possibly 20 μm.

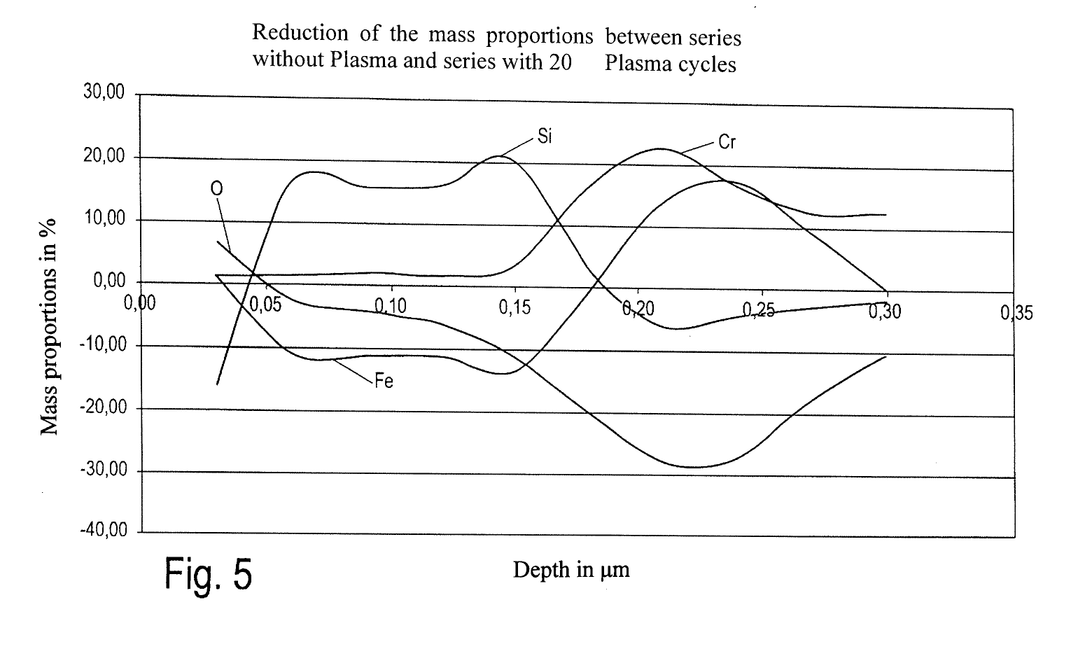

Diagram D2, or FIG. 5, shows the curve of the differences of the mass concentrations along the depth profile. The differences result from measured values of the depth profile before and after a twenty-fold pyrolysis. Chromium is intercalated in the siliceous coating or silicon-oxide-containing coating of the stainless steel surface in depth ranges below 0.03 μm. Chromium particles are enriched below and in the silicon-oxide-containing surface.

The high chromium proportion, which has diffused by pyrolysis into the SiO₂ layer formed, ensures the integrity of the plasma polymer layer in the event of scratches by formation of chromium oxide. This chromium oxide layer protects the siliceous plasma polymer layer from infiltration and detachment in the event of scratches, since no corrosion of the steel substrate occurs.

The chromium proportion of the SiO₂ layer after pyrolysis is an average of between 5-35%, or possibly an average of 25% in mass proportion.

Tempering colors due to sulfur compounds may additionally advantageously be concealed by coloration of the plasma polymer coating.

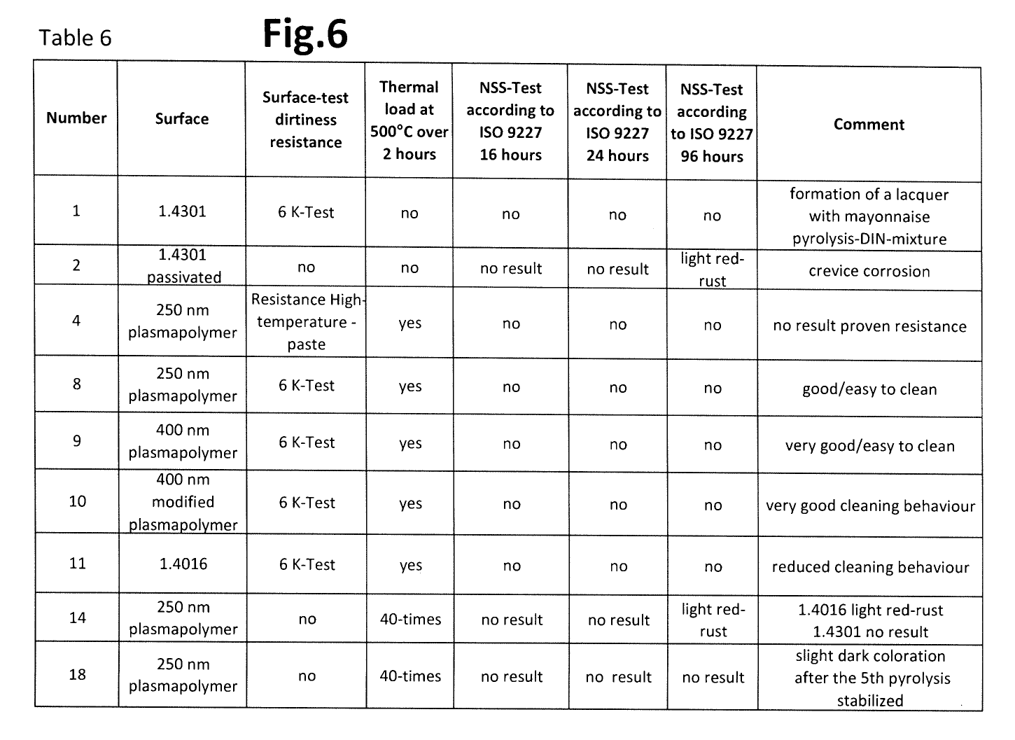

Table 6, in FIG. 6, shows experimental results with respect to the adhesion of dirt residues, the temperature stability, and the corrosion resistance.

Metal components with and without coatings and having various layer thicknesses were tested. To detect the temperature stability, a component was subjected to a temperature of 500° C. for 2 hours, which approximately corresponds to the pyrolysis conditions in a baking oven. The corrosion test was performed as per the salt spray method according to ISO 9227, the test running over a period of time of 16 hours, 24 hours, and 96 hours.

In one experimental series, a component having a stainless steel surface having the material number 1.4301, that is, an austenitic acid-resistant 18/10 chromium-nickel steel having low carbon content, was studied. It had lacquering upon the action of mayonnaise on the steel surface.

In a further experimental series, a passivated stainless steel surface 1.4301 was studied. A crevice corrosion of the surface was established in the area of the welded bond during the corrosion test.

In a following experiment, the stainless steel surface 1.4301 was provided with a plasma polymer layer of the layer thicknesses 120, 250, and 400 nm, and with a modified plasma polymer layer of the layer thickness 400 nm. Independently of the layer thickness, compatibility of the surface with respect to contaminants of grease or food residues and the like was established. Furthermore, the temperature resistance of such coated components was confirmed.

The surface test of the 6-component test was performed based on DIN-EN 60350. Common household foods were combined in the six components, which contained the spectrum of the most important materials for nutrition.

The six components contained carbohydrates, such as sugars and starches, fats, amino acids and proteins, vitamins, minerals, dietary fibers, and water. The combination ensured that the surfaces were sufficiently stressed by the chemical action during cooking. The purpose of the soiling and the subsequent cleaning was to emphasize comparability of the different surfaces. The evaluation was performed according to specifications of the above-mentioned standard.

The 6-component test series resulted in good to very good cleanability of the surface for all plasma-polymer-coated components. As a stress test for temperature stress, a pyrolytic cleaning was simulated at 500° C. over 2 hours 40 times on the coated components having different layer thicknesses, without noticeable restrictions in the functionality of the surface or in the integrity of the surface.

However, a slight darkening of the coating occurred in each case after the fifth pyrolysis.

The corrosion test was performed using coated components of the layer thicknesses 120, 250, and 400 nm employing two different stainless steels.

Coated components made of stainless steels of the material numbers 1.4301 and 1.4016, as a 17% chromium steel, were used.

The corrosion resistance was provided at all three layer thicknesses in the case of stainless steel 1.4301. The coated stainless steel 1.4016 had a slight red rust only in the case of the salt spray test over 96 hours, independently of the layer thickness of the coating.

The corrosion resistance, the temperature resistance, and also the good cleanability of the plasma-polymer-coated components, according to the present disclosure, are therefore provided.

The coating offers advantages in high-temperature usage areas, in particular in baking ovens. However, it also offers advantages in the case of components in areas having high corrosion hazard. This also includes, for example, white goods, such as refrigerators and washing machines. Furniture fittings are also subjected to higher corrosion hazard during transport, in particular in the case of overseas transport, for example, due to seawater. Coated fittings have a longer service life than uncoated fittings in these fields.

Although the present disclosure has been described and illustrated in detail, it is to be clearly understood that this is done by way of illustration and example only and is not to be taken by way of limitation. The scope of the present disclosure is to be limited only by the terms of the appended claims.

We claim:

1. A method for producing a component of a pullout guide for high-temperature applications, the method steps comprising:
producing a metal blank;
applying a plasma polymer coating to a surface of the blank;
heating the coated blank to a temperature of at least 400° C.; and
cooling the coated blank, thereby producing the component.

2. The method according to claim 1, wherein the coated blank is heated at 400-600° C. for at least 25 minutes.

3. The method according to claim 1, wherein the plasma polymer coating includes a siliceous plasma polymer having a temperature resistance in the range of 450-550° C.

4. The method according to claim 1, wherein during the heating step, a first time-dependent temperature gradient is 8-10 K/minute up to a moderate temperature and a second time-dependent temperature gradient is 10-30 K/minute up to a target temperature.

5. The method according to claim 4, wherein the target temperature is between 450-550° C.

6. The method according to claim 4, wherein the target temperature is kept constant over a period of time of 25 to 40 minutes.

7. The method according to claim 1, wherein a time-dependent temperature gradient of the cooling of the blank is 15-25 K/minute.

8. The method according to claim 1, wherein the coated blank is temperature-treated in a circulating air method having an air flow rate of 50-70 l/minute.

9. The method according to claim 1, further comprising the step of smoothing a surface of the blank before applying the plasma polymer coating.

10. The method according to claim 9, wherein the blank is smoothed to a surface roughness of less than 350 nm before applying the plasma polymer layer.

11. The method according to claim 1, further comprising the step of diffusing a metal into the plasma polymer layer, which forms a passive layer under oxygen influence, during the heating of the metal blank.

12. A metal component comprising a coating produced by the method according to claim 1.

13. The component according to claim 12, wherein the applied plasma polymer coating is a corrosion-resistant, mechanically durable silicone layer.

14. The component according to claim 13, wherein the plasma polymer layer has a layer thickness of 100-400 nm.

15. The component according to claim 13, wherein the plasma polymer layer includes 20-30%, according to mass proportions, of a metal, which forms a passive layer under oxygen influence.

16. The component according to claim 12, wherein the component includes a metal base body, an intermediate layer situated above the metal base body, which intermediate layer includes silicon oxide and at least one metal, and a cover layer being made of silicon oxide, the intermediate layer being made of silicon oxide and metal forming a passive layer for protecting the base metal body from corrosion upon damage to the cover layer.

17. The component according to claim 12, wherein one or both of the applied plasma polymer layer and the coating on the component is transparent after the cooling of the coated blank.

18. The component according to claim 12, wherein the component is implemented as a rail of a pullout guide for baking ovens.

19. The component according to claim 12, wherein the component is used in combination with household appliances, the household appliances including one or more of baking ovens, refrigerators, washing machines, and a furniture fitting.

20. The method according to claim 1, wherein the coated blank is heated at 400-600° C. for at least 20 minutes.

21. The method according to claim 1, wherein the plasma polymer coating includes a siliceous plasma polymer having a temperature resistance in the range of 300-600° C.

22. The method according to claim 4, wherein the target temperature is between 400-600° C.

23. The method according to claim 4, wherein the target temperature is kept constant over a period of time of 15 to 90 minutes.

24. The method according to claim 1, wherein a time-dependent temperature gradient of the cooling of the blank is 5-40 K/minute.

25. The method according to claim 1, wherein the coated blank is temperature-treated in a circulating air method having an air flow rate of 30-90 l/minute.

26. The method according to claim 9, wherein the component is smoothed to a surface roughness of less than 400 nm, before applying the plasma polymer layer.

27. The method according to claim 11, wherein the metal includes chromium.

28. The method according to claim 13, wherein the plasma polymer layer has a layer thickness of 50-500 nm.

29. The method according to claim 13, wherein the plasma polymer layer comprises at least 5%, according to mass proportions, which forms a passive layer under oxygen influence.

30. The component according to claim 15, wherein the metal includes chromium.
